(19) United States
(12) Patent Application Publication
(10) Pub. No.: US 2008/0064201 A1
(43) Pub. Date: Mar. 13, 2008

(54) Flip chip packaging method that protects the sensing area of an image sensor from contamination

(76) Inventor: Wen Ching Chen, Dali City (TW)

Correspondence Address: CHEN WEN CHING, P.O. BOX 2103, Taichung, omitted

(21) Appl. No.: 11/516,491

(22) Filed: Sep. 7, 2006

(51) Int. Cl. H01L 21/44

(52) U.S. Cl. 438/613

(57) ABSTRACT

A flip chip packaging method that protects a sensing area of an image sensor from contamination primarily comprises: a transmitting substrate having a surface with a predetermined area forming a metal layer thereon which includes a circuit and at least one enclosure encircling said predetermined area; providing an image sensor with the sensing area thereof disposed according to said predetermined area and the bond pads thereof electrically connected to the circuit on the surface of the transmitting substrate; and filling adhesive around the image sensor forming an airtight seal after the adhesive solidifies forming the flip chip packaging of the image sensor.

### BACKGROUND OF THE INVENTION

1. Technical Field

The present invention relates to a flip chip packaging method that protects the sensing area of an image sensor from contamination, which works by mounting at least one enclosure surrounding the sensing area and protect it from adhesive.

2. Description of Related Art

FIGS. 5 and 6 illustrates a conventional protective structure for a sensing area of an image sensor that comprises at least one conductive circuit 82 at the lower surface 81 of a transmitting substrate 8, and a semiconductor image sensor 9 electrically connected to said conductive circuit 82 of the transmitting substrate 8. Under-fill 94 is filled around the image sensor 9 to enhance the conjunction between the image sensor 9 and transmitting substrate 8 and to block external contamination. To prevent the under-fill 94 spilling into the sensing area 91 of the image sensor 9, the prior art implements an enclosure 83 in a frame form to skirt the sensing area 91 and define the bond pads 92 of the image sensor 9 on the outside. Thus, the enclosure 83 can efficiently preserve the immaculacy of the image sensor 9 sensing area 91.

The enclosure 83 may be formed in a variety of ways, such as at a predetermined position on the lower surface 81 of the transmitting substrate 8 or the periphery of the sensing area 91 of the image sensor 9 by screen printing, dispensing and depositing. Alternatively, the enclosure 83 may be prepared with injection molding by producing an independent frame, which may later be adhered at a predetermined position on the transmitting substrate 8 or at the periphery of the sensing area 91 of the image sensor 9.

However, the foresaid method for preparing an enclosure inevitably requires additional packaging procedures and in turn increases manufacturing costs. Therefore, the invention is aimed at the problem and intends to provide an improved method of preparing the enclosure.

### SUMMARY OF THE INVENTION

It is the primary object of the present invention to provide a flip chip packaging method that protects the sensing area of an image sensor from contamination that involves forming an enclosure that arranges a circuit on a transmitting substrate to simplify packaging procedures and therefore reduce manufacturing expenses.

To achieve these and other objects of the present invention, the disclosed invention comprises the following steps:

a. providing a transmitting substrate having a surface with a predetermined area defined thereon and making a metal layer thereon which includes a circuit and at least one enclosure encircling said predetermined area;

b. providing an image sensor with a sensing area thereof disposed on said predetermined area, and with the bond pads thereof electrically connected to the circuit on the surface of the transmitting substrate; and

c. filling adhesive around the image sensor to create an airtight seal, which solidifies forming the flip chip packaging of an image sensor.

### BRIEF DESCRIPTION OF THE DRAWINGS

The invention as well as a preferred mode of use, further objectives and advantages thereof, are best understood by reference to the following detailed description of an illustrative embodiment when read in conjunction with the accompanying drawings, wherein:

FIG. 1 is a schematic view of a transmitting substrate according to the present invention.

FIG. 2 is a schematic vertical view of the transmitting substrate according to FIG. 1.

FIG. 3 is a schematic view of the transmitting substrate combined with an image sensor according to the present invention.

FIG. 4 is a partial enlarged view of the packaged image sensor according to the present invention.

FIG. 5 is a schematic view of the protective structure according to a prior art.

FIG. 6 is a vertical view according to FIG. 5.

### DETAILED DESCRIPTION OF THE PREFERRED EMBODIMENT

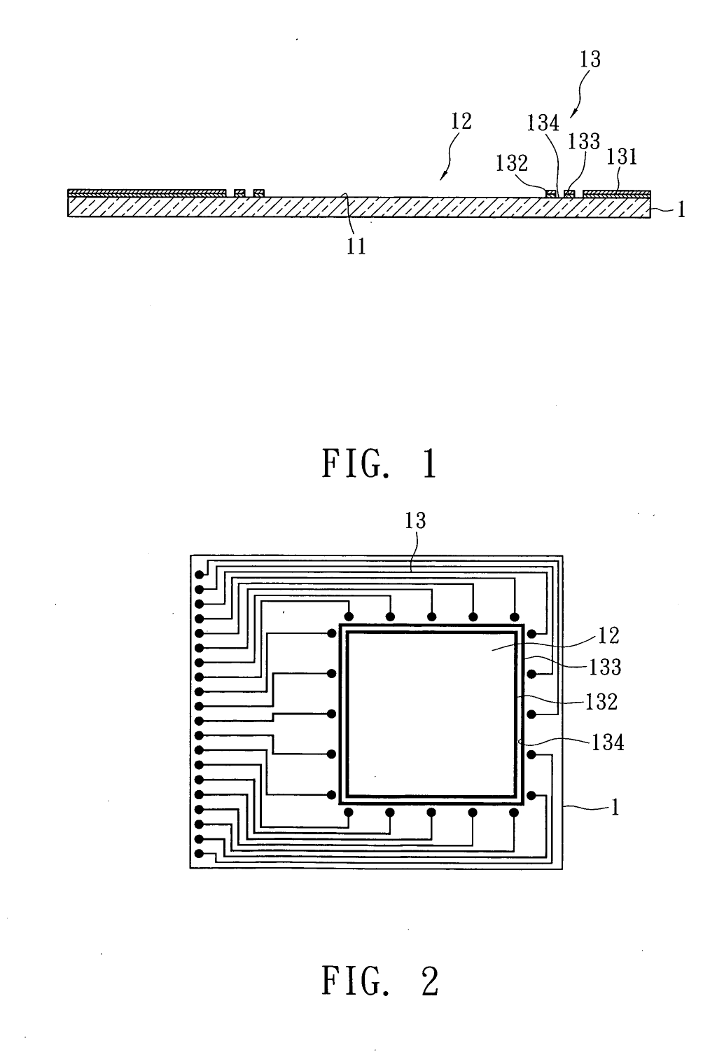

Please refer to FIGS. 1 to 4 for a preferred embodiment of the present invention. It is to be understood that the recited embodiment is for the purpose of illustration and not intended to limit the present invention with the discussed structure.

The flip chip packaging method that protects a sensing area of an image sensor from contamination according to the particular embodiment primarily comprises following steps:

a. providing a transmitting substrate 1 having a surface 11 with a predetermined area 12 defined thereon and making a metal layer 13 thereon which includes a circuit 131 and at least one enclosure encircling said predetermined area 12 made by screen printing, dispensing and depositing, wherein, according to this embodiment, the metal layer 13 has two enclosures 132, 133 wherein the enclosure 132 closely encloses the predetermined area 12 and the enclosure 133 encloses the enclosure 132 with an interval 134 spacing in between, as shown in FIG. 1 and FIG. 2.

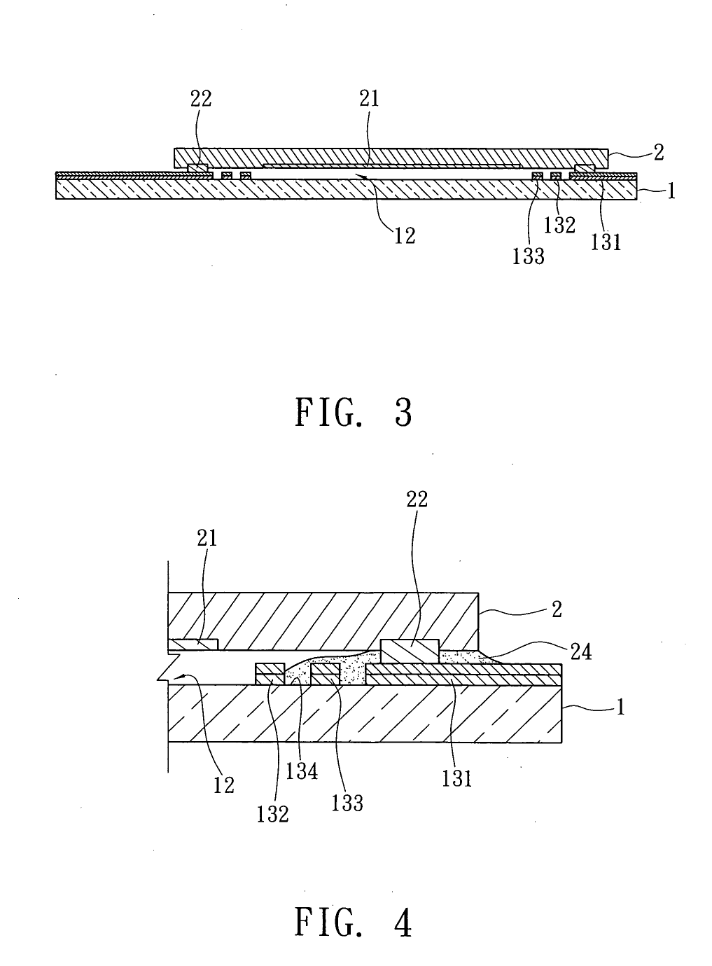

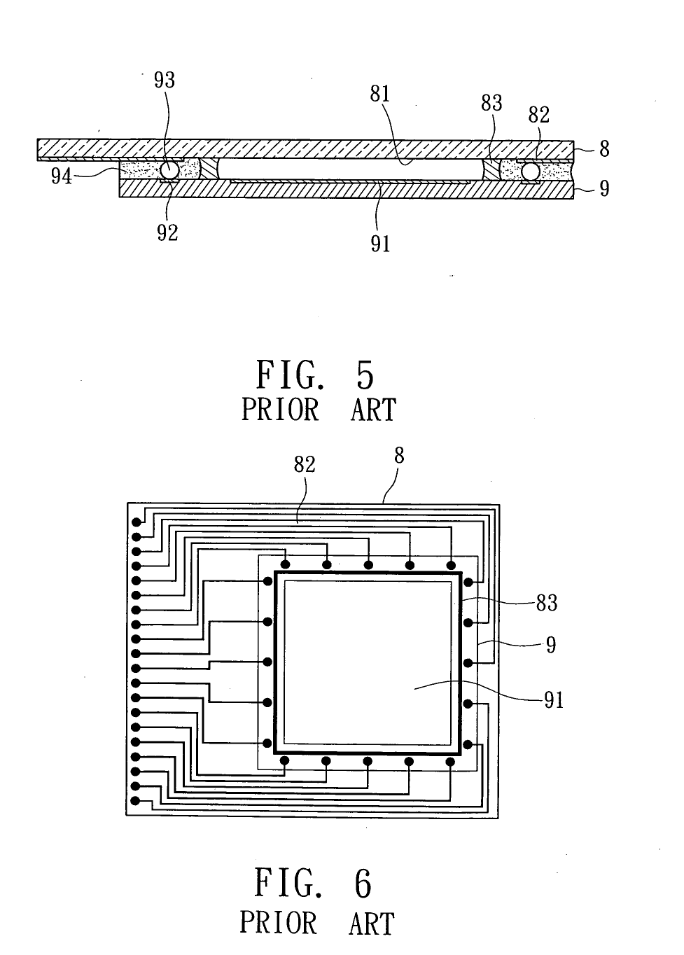

b. providing an image sensor 2 mounted on the surface 11 of the transmitting substrate 1 and making the sensing area 21 thereof corresponding to said predetermined area 12 of the transmitting substrate 1 and making each bond pad 22 of the image sensor 2 electrically connected to the circuit 131 on the surface 11 of the transmitting substrate as shown in FIG.3 by means of reflow soldering, wherein, for instance, a method of electrically connecting the bond pad 22 to the circuit 131 may comprise: in Step a, after making a metal layer 13 on the surface 11 of the transmitting substrate 1, further plating a tin or tin alloy layer thereon to provide tin for forming an alloy with the gold surface of the bond pads 22 that renders final soldering connection between the bond pads 22 and the circuit 131 so that the interval between the transmitting substrate 1 and image sensor 2 can be minimized and the height of the enclosure 132 can also be increased; and wherein, the invention can be also embodied through normal soldering method by embedding tin balls; and

c. filling adhesive 24 around the image sensor 2 forming an airtight seal and after the adhesive 24 solidifies, the flip chip packaging of the image sensor is therefore achieved.

The method of the present invention is characterized by completing the prearranged circuit 131 and the two enclosure 132, 133 encircling the predetermined area simultaneously when making the metal layer 13 on the surface 11 of the transmitting substrate 1. When the filling adhesive 24 around the image sensor 2 on the surface 11 of the transmitting substrate 1 during flip chip packaging, as the enclosures 132, 133 encloses the predetermined area perform as protecting walls, the flowing adhesive 24 may be first barricaded before the outer enclosure 133 and if it keeps flowing toward the center of the sensor 2, it enters the interval 134 between the enclosures 132, 133 and is blocked before the inner enclosure 132. Thereupon, the adhesive 24 is efficiently kept away from flowing into the sensing area 21 of the image sensor 2 by the presence of the enclosures 132, 133.

Through above description of the embodiment, it is apparent that the disclosed invention is to simplify the flip chip packaging procedures and in turn reduce manufacturing expense by forming an enclosure synchronously while arranging a circuit on the surface of a transmitting substrate.

What is claimed is:

1. A flip chip packaging method that protects a sensing area of an image sensor from contamination comprising the following steps:
a. providing a transmitting substrate having a surface with a predetermined area defined thereon and making a metal layer thereon which includes a circuit and at least one enclosure encircling said predetermined area;
b. providing an image sensor with the sensing area thereof deposited corresponding to said predetermined area and making each bond pad thereof electrically connected to the circuit on the surface of the transmitting substrate; and
c. filling adhesive around the image sensor forming an airtight seal, and after the adhesive solidifies, the flip chip packaging of the image sensor is therefore achieved.

2. The flip chip packaging method of claim 1, wherein in Step a, after a metal layer is formed on the surface of the transmitting substrate, a tin or tin alloy layer is next plated thereon.
